(19) United States
(12) Patent Application Publication
(10) Pub. No.: US 2024/0211664 A1
(43) Pub. Date: Jun. 27, 2024

(54) DIGITAL SIMULATION OF A MULTI-SCALE COMPLEX PHYSICAL PHENOMENON BY MACHINE LEARNING

(71) Applicant: EXTRALITY, PARIS (FR)

(72) Inventors: Louis VERRET, Sèvres (FR); Ahmed MAZARI, PARIS (FR); Thibaut MUNZER, Paris (FR); Pierre YSER, Savigny sur Orge (FR)

(21) Appl. No.: 18/556,950

(22) PCT Filed: Apr. 26, 2021
(86) PCT No.: PCT/FR2021/050721

§ 371 Date: Oct. 24, 2023

(51) Int. Cl. G06F 30/28

(52) U.S. Cl. CPC G06F 30/28

(57) ABSTRACT

The disclosure relates to a neural network configured for a numerical simulation of a physical phenomenon, such as a fluid flow, a thermal transfer or a calculation of a mechanical structure, by joint learning from physical data of several types correlated with each other from a plurality of numerical training simulations.

### CROSS REFERENCE TO RELATED APPLICATIONS

This application is a National Stage of International Application No. PCT/FR2021/050721, having an International Filing Date of 26 Apr. 2021, which designated the United States of America, and which International Application was published under PCT Article 21(2) as WO Publication No. 2022/229517 A1, the disclosure of which is incorporated herein by reference in its entirety.

### BACKGROUND

### Field

The field of the disclosure is that of numerical simulation.

More specifically, the disclosure relates to a method for numerical simulation of a complex multi-scale physical phenomenon by machine learning.

The disclosure finds particular applications for simulating a complex physical phenomenon of the fluidic type (e.g.: flow of a fluid, two-phase flow, tracking of particles, etc.), of the structural type (e.g.: strength of a structure) and/or of the thermal type (e.g.: conduction, convection, radiation). A particular application of the disclosure is multiphysical simulation, combining several types of phenomena, such as for example natural or forced convection around an object, etc.

### BRIEF DESCRIPTION OF RELATED DEVELOPMENTS

Techniques are known in the prior art for simulating a physical phenomenon by discretizing a space with a continuous mesh of elements wherein differential equations representative of the physical phenomenon are calculated. The simulation is obtained when the calculation converges towards a result respecting predetermined boundary conditions as well as continuity of physical data between two contiguous elements discretizing the space. This type of simulation is generally called CFD (computational fluid dynamics) when simulating a fluid flow, or FEA (finite element analysis) when calculating a mechanical structure, for example of the strength of materials type.

The major disadvantage of these prior techniques is that they generally consume a lot of computer resources, depending on the size of the mesh used to discretize the simulation space. For example, it is common to obtain a consistent simulation result after hundreds or even thousands of CPU (acronym for “Computer Processor Unit”) hours, making numerical simulation expensive and difficult to apply in an optimization context.

In order to improve the efficiency of simulation calculation time, numerical simulation techniques by machine learning have been developed, implementing deep learning techniques in order to obtain a result by prediction in comparison with results calculated previously on similar problems.

For example, from the prior art the numerical simulation technique is known, described in the article by Li et al. which was published in 2019 and which concerns a deep learning variational solver based on a domain decomposition method called D3M (acronym for “Deep Decomposition Method”) to implement parallel calculations in physical subdomains of the simulation.

The major disadvantage of this technique is that it is based on reconstitution of the simulation from the result of the simulation in each subdomain. However, the intersection between each subdomain poses notable difficulties in the simulation because the boundary conditions are only updated after reconstitution, thereby leading to excessive consumption of calculation time.

In order to improve calculation efficiency and consequently the consumption of computer resources, the Applicant has filed in this field French patent application No. 1914967 which relates to a numerical simulation method by machine learning, based on local predictions carried out sequentially from machine learning of global simulations carried out previously.

There is, however, a need to further improve calculation efficiency during numerical simulation of a complex physical phenomenon. This disclosure falls within this framework.

### SUMMARY

To this end, the disclosure is aimed at a neural network configured for a numerical simulation of a physical phenomenon, such as a fluid flow, a thermal transfer or a calculation of a mechanical structure, in a space including a plurality of points of interest linked to a geometry included in space.

It can be any space, generally comprising an object around which and/or wherein the flow to be simulated takes place. The surface points of interest generally correspond to points on the surface of the object. They can also be points serving as boundary conditions on the edge of the space used for the simulation.

It should be emphasized that the geometry can be included inside the simulation space, as in the case of flow around an airplane wing and/or at the edge of the simulation space, as in the case of flow in a channel.

Volumetric points of interest generally correspond to points called measurement points for which simulation data are expected, which can also be defined in the simulation space.

Furthermore, the numerical simulation object of the configuration of the neural network is defined by at least one condition of the numerical simulation.

Such a condition of the numerical simulation generally corresponds to a boundary condition such as, for example, a speed linked to the geometry in the simulation space in the case of a flow around a geometry in movement, an ambient temperature, a coefficient of turbulence, etc.

According to the disclosure, the neural network comprises:
a layer for encoding surface points of interest and the condition(s) of the numerical simulation in a vector representative of the simulation; and
a layer for generating a simulation result comprising simulation values of at least two different types from the vector representative of the simulation, the simulation values of different types being correlated with each other;

each layer of the neural network being configured by parameters previously generated during a learning phase of a plurality of numerical simulations called numerical training simulations.

In this way, by learning from data correlated with each other, coming from one, or preferably from several, numerical training simulations, it is possible to obtain a simulation result more efficiently by reducing the energy consumption of a computer processor processing the numerical simulation method. Indeed, by mixing data of different types during learning—namely surface data, volumetric data and/or global coefficients—the results of the simulation of a physical phenomenon in the simulation space, discretized by a mesh, can be obtained more efficiently because the result is obtained by concomitantly predicting correlated simulation values of several types. In other words, since the simulation values are correlated, they make it possible to improve the prediction obtained by the machine learning algorithm very significantly, while maintaining consistency between simulation values of different types.

It should be emphasized that the correlated simulation values, which can also be called correlated data, generally interact with each other in the equations governing the physical phenomenon being simulated and that it is therefore advantageous to learn this correlation between data of different types when configuring the neural network.

Simulation values of different types can be spatially and/or temporally correlated.

Preferably, simulation values are of distinct types from the following:
a volumetric datum such as a pressure or velocity vector;
a surface datum such as a pressure force or a temperature;
a global coefficient such as a coefficient of heat transfer or a global drag force;
a curve evolving over time of a volumetric datum;
a curve evolving over time of a surface datum;
a curve evolving over time of a global coefficient.

By volumetric datum is meant a datum linked to observation points in 3D space surrounding the geometry (surface datum). A volumetric datum is, for example, a pressure or a velocity vector.

By surface datum is meant a datum located on a surface. A surface datum is, for example, a pressure force or a temperature.

By global coefficient is meant a parameter resulting from a global integral on the set of physical dimensions of the simulated problem. A global coefficient corresponds, for example, to the integral of pressure forces on the geometry of a boat. A global coefficient is, for example, a coefficient of heat transfer or a global drag force.

For example, on a point of interest on the surface of an object, the pressure is directly related to the velocity vector of the fluid at this point of interest and those in the near vicinity of the volume. The temperature of the fluid at this point is also related to the velocity vector and also to the heat transfer coefficient.

This correlation can also be more global. For example, there is a correlation between the drag behind a wing or a boat and the force of pressure in front of the wing or boat.

In particular aspects of the disclosure, the layer for generating a simulation result comprises:
a sub-layer for generating at least one simulation value for all or part of the surface points of interest from the vector representative of the simulation;
a sub-layer for generation of at least one simulation value as a global parameter of the simulation from the vector representative of the simulation.

In particular aspects of the disclosure, the space also includes a plurality of volumetric points of interest around the geometry and the neural network comprises a layer for encoding all or part of the volumetric points of interest in a matrix called a representative matrix of the representative matrix of the volumetric measurement points. In addition, the layer for generation of a simulation result comprises:
a sub-layer for generation of at least one simulation value for all or part of the volumetric points of interest from the vector representative of the simulation and a matrix representative of the volumetric measurement points;

and at least one sub-layer from the following:
a sub-layer for generating at least one simulation value for all or part of the surface points of interest from the vector representative of the simulation;
a sub-layer for generation of at least one simulation value as a global simulation parameter from the vector representative of the simulation.

In particular aspects of the disclosure, the layer for encoding surface points of interest and the condition(s) of the numerical simulation comprises:
a module for development of an intermediate vector representative of the geometry and
a module for generation of the vector representative of the simulation by association of the intermediate vector representative of the geometry with a vector including the condition(s) of the simulation.

In particular aspects of the disclosure, the layer for encoding the surface points of interest comprises an intermediate sub-layer for encoding surface points of interest in a matrix representative of the geometry.

In particular aspects of the disclosure, the module for generation of the intermediate vector representative of the geometry comprises a sub-module for compression of the matrix representative of the geometry in order to obtain the intermediate vector representative of the geometry.

In particular aspects of the disclosure, the compression sub-module is of a type from among “Max Pooling”, “Average Pooling” or “Sum Pooling”.

In particular aspects of the disclosure, the compression sub-module corresponds to a decreasing cascade of neural network sub-layers.

Thanks to the decreasing cascade, the matrix representative of the geometry is progressively reduced in number of lines until the intermediate vector representative of the geometry is obtained.

In particular aspects of the disclosure, the intermediate sub-layer for encoding the surface points of interest corresponds to an increasing cascade of sub-layers of the neural network.

This increasing cascade makes it possible in particular to increase the number of characteristics associated with each surface point of interest, with the aim of having a better understanding of the neural network and consequently a better ultimate prediction. The number of characteristics used by the encoding can be compared to the spatial resolution of an image. The higher the spatial resolution, the better the image definition and detail.

The increase is generally gradual, rising, for example, to 128 characteristics, 512 characteristics then to 2048 characteristics. It should be emphasized that the number of characteristics that corresponds, in other words, to an encoding resolution is different from the number of characteristics physically associated with the surface point of interest, such as the coordinates in three-dimensional space, the normal of the surface, the radius of curvature, or physical data such as a surface temperature, surface roughness, etc.

In particular aspects of the disclosure, the layer for generating a simulation result comprises a decreasing cascade of sub-layers of the neural network configured to generate at least one simulation value.

The layer for generation of a result, which corresponds, in other words, to a decoding, thereby uses a decreasing cascade wherein the number of characteristics associated with the points of interest is progressively reduced in order to obtain interpretable physical characteristics, that is, the values of the simulation result.

In particular aspects of the disclosure, the neural network is of the “Multi-Layer Perceptron” (MLP) or “Convolutional Neural Network” (CNN) type.

An MLP-type neural network can also be called a multi-layer perceptron.

The disclosure also relates to a method, implemented by computer, for numerical simulation of a physical phenomenon, such as flow of a fluid, heat transfer or a mechanical structure calculation, in a space including a plurality of surface points of interest linked to a geometry included in space.

Such a numerical simulation method advantageously comprises a step for prediction of a simulation result by means of a neural network according to any of the preceding aspects, the simulation result comprising simulation values of at lease two different types, correlated with each other.

In particular aspects of the disclosure, the method also comprises a learning phase during which parameters configuring each layer of the neural network are generated by learning from a plurality of numerical simulations called numerical training simulations.

In particular aspects of the disclosure, the encoding is carried out using a cascade of increasing sampling characteristic numbers and/or the decoding is carried out using a cascade of decreasing sampling characteristic numbers.

The disclosure also related to a computer program product, stored in a computer memory, comprising instructions configuring a computer processor for implementation of a numerical simulation method according to any of the preceding implementation modes.

The computer memory notably comprises the instructions for implementation of the neural network according to any of the preceding aspects.

Finally, the disclosure relates to a method for configuration of a computer processor to simulate a physical phenomenon according to the implementation of a simulation method conforming to any of the preceding implementation modes, comprising steps for:
receiving instructions for the simulation method, stored in a computer memory;
obtaining a result of simulation of the physical phenomenon from the processing of said instructions, the result of the simulation comprising simulation values of at least two different types, correlated with each other.

### BRIEF DESCRIPTION OF FIGURES

Other advantages, aims and particular characteristics of the present disclosure will emerge from the following non-limiting description of at least one particular aspect of the devices and methods which are the subject of the present disclosure, with reference to the appended drawings, wherein:

FIG. 1 is a schematic view of an example aspect of a neural network according to the disclosure, implemented to perform a numerical simulation of a physical phenomenon;

FIG. 2 is a schematic diagram of the numerical simulation method of FIG. 1;

FIG. 3 is a schematic diagram of a method of configuring a computer processor for implementing the numerical simulation method of FIGS. 1 and 2.

### DETAILED DESCRIPTION

The present description is given as non-limiting, each characteristic of an aspect being able to be combined with any other characteristic of any other aspect in an advantageous manner.

Note, from here on, that the figures are not to scale.

### Example of a Particular Aspect

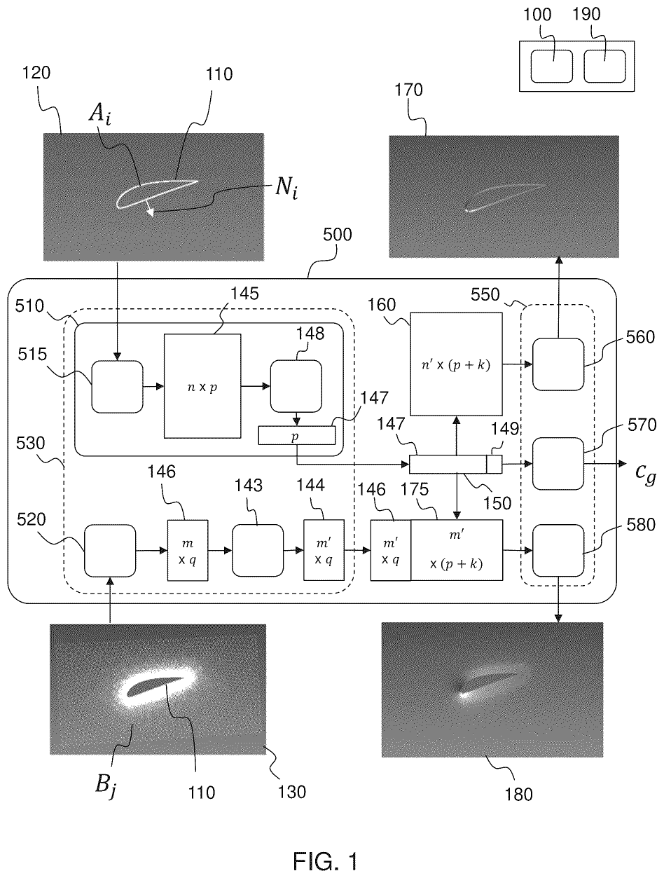

FIG. 1 illustrates a non-limiting example aspect of a neural network 500 according to the disclosure, implemented during a numerical simulation method of a physical phenomenon whose instructions are processed by a computer processor 100. The neural network 500 is advantageously configured according to the disclosure to enable a numerical simulation of the physical phenomenon in a more efficient manner compared to the simulation methods of the prior art.

The physical phenomenon, object of the simulation illustrated in FIG. 1, corresponds in the present non-limiting example to flow of a fluid in the vicinity of a geometry 110. More precisely, geometry 110 is here an airplane wing profile moving at a constant speed in air. A person skilled in the art will have no difficulty adapting this example to the simulation of other types of physical phenomena whether combining or not one or more types, in particular fluidic, structural or thermal. A simulation of a flow, wholly or partly inside a geometry, can also be envisaged.

The simulation in the present non-limiting example of the disclosure defines by one condition, namely the speed of geometry 110 in the simulation space which is two-dimensional for the sake of clarity of the illustration.

In variants of this particular mode of implementation of the disclosure, the simulation is carried out in a three-dimensional simulation space. A time variable may also be integrated on another scale, third or fourth scale depending on the case, to carry out a dynamic simulation.

The surface of geometry 110 is represented by points of interest Aᵢ (i=1 . . . n) called surface areas, illustrated on the input image 120, each possibly associated with a vector normal Nᵢ to the surface. The points of interest Aᵢ are here central points of elements defining the surface of the simulation object. Each point of interest Aᵢ is here defined by f physical characteristics, including the coordinates of the point of interest Aᵢ, or even the normal vector Nᵢ or physical values such as a surface temperature or a surface roughness coefficient.

The neural network 500 comprises a layer 510 for encoding surface points of interest Aᵢ and the conditions of the numerical simulation in a vector 150 representative of the simulation.

For this purpose, the surface points of interest Aᵢ are initially encoded in a matrix 145 of size n×p by a sub-layer 515 of the encoding layer 510 of the neural network 500. The whole number p, greater than the number f of physical characteristics, corresponds to a characteristic sampling number making it possible to detail the surface points Aᵢ. The greater the sampling characteristic number, the better the surface points Aᵢ will be characterized precisely. In other words, the characteristic sampling number can be considered in the same way as the spatial resolution of an image. The higher the spatial resolution (for example 300 instead of 100 ppi), the better the image will be defined and the more precise the image details will be.

It should be emphasized that for the encoding of surface points, taking into account the normals Nᵢ can advantageously be carried out in order to obtain a more representative encoding of the volume of the geometry 110, in particular to know the orientation of the geometry 110 relative to the flow.

The sub-layer 515 can in practice correspond to an increasing cascade of sub-layers of the neural network, increasing with each successive sub-layer the number of sampling characteristics, such as for example 128, 512, 2048, in order to increase the precision of the encoded points and therefore the prediction ultimately obtained. It should be emphasized that the greater the number of sampling characteristics, the better defined the high gradient physical phenomena can be.

The matrix 145 is then compressed in a second step by a compression module 148 commonly known as “Max Pooling”. This “Max Pooling” process makes it possible to reduce the matrix 145 to a vector 147 of size p, which is representative of the geometry 110, in particular taking the maximum value of each column of the matrix 145. Alternatively, other processes for compressing a matrix into a vector can be envisaged, such as performing a sum or an average of the values of a column for example. These techniques are generally known respectively as “Sum Pooling” and “Average Pooling”. A descending cascade of sub-layers of the neural network can also be envisaged to reduce the matrix 145.

Vector 147 with size p obtained is then advantageously concatenated with a vector 149 including the conditions of the simulation, here the speed of the geometry 110 which is here a two-dimensional vector but which can be a three-dimensional vector in the context of a three-dimensional simulation, in order to obtain a vector 150 of size p+k representative of the simulation to be calculated. It should be emphasized that in variants of implementation of the disclosure, several conditions of the simulation can be concatenated to the vector of size p, such as, for example, an ambient temperature, an atmospheric pressure, etc.

Points of interest Bⱼ (j=1 . . . m) called volumetric can also be chosen in the fluid flow in the vicinity of the geometry 110. Among the m volumetric points of interest Bⱼ illustrated on the second input image 130, are selected m′ points corresponding to points, called measurement points, for which simulation values around the geometry are expected.

The neural network 500 then comprises a layer 520 for encoding volumetric points of interest Bⱼ in a matrix 146, of size m×q which is then reduced, via a module 143 of the neural network 500 to a matrix 144 representative of volumetric measurement points, of size m′×q, by selecting the m′ volumetric measurement points among the m volumetric points of interest Bⱼ for which a physical value is expected.

Each point of interest Bⱼ is here defined by g physical characteristics, including the coordinates of the point of interest Bⱼ, or even physical values such as, for example, a temperature, a speed or a pressure.

As with sub-layer 515, the encoding layer 520 can comprise an increasing cascade of sub-layers of the neural network, increasing the number of sampling characteristics with each successive sub-layer.

Layers 510 and 520 are thereby included in a first part 530 of the neural network 500, known as the encoding part. During this first part 530, successive encodings can be carried out in the encoding layers 510 and 520 by increasing at each step the characteristic sampling number in order to capture increasingly precise details.

The vector 150 representative of the simulation and the matrix 144 representative of the volumetric measurement points is then used by a second part 550 of the neural network 500, called decoding, making it possible to predict the result of the simulation of the physical phenomenon.

For this purpose, the second part 550 of the neural network 500 comprises a layer 560 for generating a simulation value for all or part of the surface points of interest Aᵢ of geometry 110, namely n′ surface points of interest Aᵢ, from a matrix 160 formed by n′ representative vectors 150 of the simulation, i.e. a vector 150 for each surface point of interest Aᵢ for which a simulation value is expected. The simulation values so obtained are illustrated in image 170.

The decoding part 550 of the neural network 500 also comprises a layer 570 for generating a global parameter c_{g}, as a simulation value, from the vector 150 representative of the simulation. It should be emphasized that several global parameters can also be predicted by the layer 570.

When volumetric points of interest Bⱼ are initialized, the decoding part 550 of the neural network 500 also comprises a layer 580 for generating a simulation value for all or some of the points of interest Bⱼ, here the m′ volumetric measurement points, from the vector 150 representative of the simulation and matrix 144 representative of the volumetric measurement points. More precisely, the layer 580 processes a matrix 175 associating the matrix 146 representative of the m′ volumetric measurement points with m′ vectors 150 representative of the simulation. The simulation values at the volumetric points of interest Bⱼ so obtained are illustrated in image 180.

Conversely to the encoding part 530, successive decodings can be carried out in the decoding layers 560 and 580 by reducing at each step the characteristic sampling number in order to extract increasingly precise values from the simulation result. A cascade of decreasing sampling characteristic number is thereby implemented.

For each surface point of interest Aᵢ and for each volumetric point of interest Bⱼ simulation values are thus obtained, each characterized respectively by f′ characteristics and g′ characteristics, for example, a pressure, a speed, a temperature, etc. The number f′ is of course less than (p+k), while the number g′ is less than (p+k+q).

It should be emphasized that the neural network 500, which is here of the MLP type, was advantageously trained previously during a learning phase on a plurality of numerical training simulations in order to generate the parameters of each layer 510, 520, 560, 570, 580 of the neural network 500.

Thus, thanks to this joint training of all the layers of the neural network 500, the correlation of data of different types (surface, volumetric, global coefficients) is advantageously preserved by learning. The simulation results predicted by the neural network 500 therefore remain consistent.

For example, the results obtained with the computer processor 100 are significantly better with the numerical simulation method of the disclosure than those of the prior art. A gain in precision and calculation time was thus observed compared to the simulation by prediction method as described in the Applicant's patent application No. 1914967. In particular, the error rate has been reduced to a value of less than 5%. The calculation time to obtain the simulation results with the same convergence criteria has been reduced by a factor of around 10. It should be emphasized that the simulation result is directly predicted by the neural network 500 without the use of iterations, which consume computer resources, as in the previous simulation method by prediction.

The simulation method 200 is advantageously stored in the form of instructions in a computer memory 190 connected to a computer processor 100.

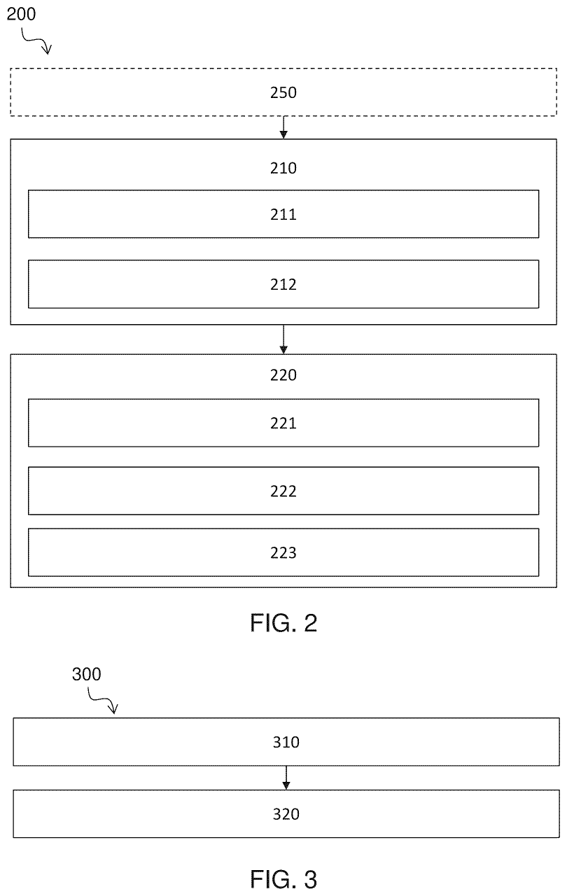

FIG. 2 represents the method 200 of numerical simulation of the physical phenomenon in the form of a schematic diagram.

Method 200 comprises a first step 210 of initializating simulation parameters, and in particular of encoding surface Aᵢ and volumetric Bⱼ points of interest, and simulation conditions by the encoding part 530 of the neural network 500.

First step 210 comprises a first sub-step 211 for encoding the surface points of interest Aᵢ and the conditions of the numerical simulation in the vector 150 representative of the simulation. This encoding, implemented by the layer 510 of the neural network 500, is notably based on a PointNet type architect making it possible to classify points of a geometry, or even to carry out a segmentation of the geometry. Such a method is described, for example in, Qi, Charles R., et al. “Pointnet: Deep learning on point sets for 3d classification and segmentation.” (Proceedings of the IEEE conference on computer vision and pattern recognition. 2017).

First step 210 can also comprise a second sub-step 212 for encoding volumetric points of interest Bⱼ in the matrix 144 representative of the volumetric measurement points, which can generally correspond to a reduction of the matrix 146 encoding the volumetric points of interest Bⱼ when a selection of measurement points among the volumetric points Bⱼ is performed. This second sub-step 212 is implemented by the optional layer 520 of the neural network 500.

During this encoding, a larger sampling of volumetric points of interest Bⱼ in regions of interest can advantageously be carried out in order to learn the spatial frequencies of the underlying functions, for example pressure or speed.

For example, in the case of simulation of a flow around a slender geometry, such as a train set, large variations in flow are present in the vicinity of the geometry.

It can therefore be advantageous to consider the probability of distribution of a point during the simulation taking into account this privileged axis, corresponding, for example, to the axis x. In this particular example, the distribution probability of a point Bⱼ can then be written:

$$Pr ( {x}_{i} ) = \frac{{e}^{- \frac{{‖ {x}_{i} - {y}_{i} ‖}^{2}}{{h}^{2}}}}{{\sum }_{i} {e}^{- \frac{{‖ {x}_{i} - {y}_{i} ‖}^{2}}{{h}^{2}}}}$$

where yᵢ represents the projection of xᵢ on axis x (considering, for example, that the geometry is centered around axis x), xᵢ the geometry points on a given 3D grid, and h a hyperparameter that controls how the Gaussian probability curve decays to zero. When the value of h is small, there is higher sampling of points in the vicinity of the axis of x.

In the present example of simulation around an aircraft wing profile, illustrated in FIG. 1, sampling of volumetric points of interest Bⱼ is higher in the region in the immediate vicinity of the aircraft wing 110. This region is considered a region of interest for the simulation.

Optionally, when the 3D coordinates of points Bⱼ are directly provided as input, the 3D coordinates are associated with a larger three-dimensional space in order to better learn the high frequency functions based on Fournier characteristics, as described in the article by Tancik et al. titled “Fourier features let networks learn high frequency functions in low dimensional domains” (preprint arXiv, 2020).

When simulation input data are encoded, prediction of the simulation result is carried out during a second step 220 of the method 200, using the second part 550 of the neural network 500.

The decoding part 550 predicts, in the present non-limiting example of the disclosure, simulation values according to at least two types of correlated data of the following:
a global simulation parameter c_{g} using layer 570 of the neural network 500 during a sub-step 221;
a surface datum, i.e., a physical datum at at least one surface point of interest Aᵢ, using layer 560 of the neural network 500 during a sub-step 222; and
a volumetric datum, i.e., a physical datum at at least one volumetric point of interest Bⱼ, using layer 580 of the neural network 500 during a sub-step 223.

Weight matrices can be used during the prediction to better estimate simulation values at the surface Aᵢ and/or volumetric Bⱼ points of interest.

It should also be emphasized that the predictions are more or less precise depending on the number of characteristics used during sampling. For example, it cannot be excluded that the results obtained are smoothed due to an insufficient number of characteristics because the high frequency functions can then by averaged over too large an interval. Careful selection of surface Aᵢ and volumetric Bⱼ points can therefore be made to improve the prediction results, by refining the points in areas likely to have a strong gradient.

In order to predict a simulation result which is consistent, parameters configuring each layer of the neural network 500 are generated by learning from a plurality of numerical training simulations during a preliminary learning phase 250.

It should be emphasized that the numerical training simulations are generally calculated by conventional CFD methods using highly refined meshes in order to allow better learning from the data. The training data base comprising these numerical simulations can also be supplemented by numerical simulations resulting from prediction, for example, by the present simulation method.

Furthermore, when the neural network 160 is configured to predict simulation data of a given physical phenomenon. learning by the neural network 160 is generally essentially carried out on simulation results of a similar physical phenomenon. For example, when the purpose of the prediction is simulation of a fluid flow, learning is essentially carried out on simulations of a fluid flow.

Thanks to the joint learning of different encoding and decoding layers on data of different types (global coefficients, surface values or even volumetric values) but correlated between them, learning by the neural network 500 is better and makes it possible to obtain a neural network 500 configuration and consequently of the computer processor 100, which is more effective in predicting consistent simulation results. It should be emphasized that learning from data correlated with each other ultimately makes it possible to obtain a better prediction because it preserves the correlation of the data which interacts with each other in the physical equations governing the simulated physical phenomena.

Several combinations of physical phenomena can also be advantageously used during learning in order to improve the parameters of the neural network 500 and consequently the prediction made, particularly in the context of multi-physical simulation. For example, for a simulation of convection around an object, comprising a problem of fluid flow, thermal flow, conduction in the object, or even mechanical deformation of the object, it may be advantageous to train the neural network with a plurality of simulations each combining one or more of these problems, all of the problems being included in the learning database.

FIG. 3 represents in the form of a schematic diagram a method 300 of configuring the computer processor 100 to simulate the physical phenomenon.

Configuration method 300 comprises a first step 310 of receiving instructions of the simulation method 200, which are stored in the computer memory 190.

These instructions are then processed during a second step 320 in order to obtain the simulation result of the physical phenomenon, the result comprising correlated data.

### Other Advantages and Optional Features of the Disclosure

In variants of the example of the preceding aspect, the neural network is configured to process and predict only surface data and global coefficients, or surface and volumetric data, or global coefficients and volumetric data.

It should also be emphasized that at least one temporal evolution curve can be used, as input or output, to replace or complement one of the types of data used or predicted by any of the neural networks described previously.

It should also be emphasized that the disclosure can be configured to process and predict any number of correlated data at the same time, such as for example, without limitation, global coefficients, surface data, volumetric data and/or temporal evolution curves.

In alternative aspects, the vector representative of the simulation is in fact a matrix comprising h lines instead of a single line. The numbers n′ and m′ are then chosen as being a multiple of h.

What is claimed is:

1. A neural network configured for a numerical simulation of a physical phenomenon, such as a fluid flow, a thermal transfer or a calculation of a mechanical structure, in a space including a plurality of surface points of interest Aᵢ linked to a geometry comprised in space, the numerical simulation being defined by at least one condition of the numerical simulation, characterized in that it comprises:
a layer for encoding surface points of interest Aᵢ and the condition(s) of the numerical simulation in a vector representative of the simulation; and
a layer for generating a simulation result comprising simulation values of at least two different types from the vector representative of the simulation, the simulation values of different types being correlated with each other;
each layer of the neural network being configured by parameters previously generated during a learning phase of a plurality of numerical simulations called numerical training simulations.

2. The neural network according to claim 1, wherein the simulation values are of types included among:
a volumetric datum;
a surface datum;
a global coefficient;
a curve evolving over time of a volumetric datum;
a curve evolving over time of a surface datum;
a curve evolving over time of a global coefficient.

3. The neural network according to claim 1, wherein the simulation values of different type are correlated spatially and/or temporally.

4. The neural network according to claim 1, wherein the generation layer of a simulation result comprises:
a sub-layer for generation of at least one simulation value for all or part of the surface points of interest Aᵢ from the vector representative of the simulation;
a sub-layer for generation of at least one simulation value as a global parameter of the simulation from the vector representative of the simulation.

5. The neural network according to claim 1, wherein the space also includes a plurality of volumetric points of interest Bⱼ around the geometry, wherein the neural network comprises a layer for encoding all or part of the volumetric points of interest Bⱼ in a representative matrix of volumetric measurement points, and wherein the layer for generation of a simulation result comprises:
a sub-layer for generation of at least one simulation value for all or part of the volumetric points of interest Bⱼ from the vector representative of the simulation and a matrix representative of the volumetric measurement points;
and at least one sub-layer from the following:
a sub-layer for generation of at least one simulation value for all or part of the surface points of interest Aᵢ from the vector-representative of the simulation;
a sub-layer for generation of at least one simulation value as a global parameter of the simulation from the vector representative of the simulation.

6. The neural network according to claim 1, wherein the layer for encoding surface points of interest Aᵢ and the condition(s) of the numerical simulation comprises:
a module for development of an intermediate vector representative of the geometry and
a module for generation of the vector representative of the simulation by association of the intermediate vector representative of the geometry with a vector including the condition(s) of the simulation.

7. The neural network according to claim 6, wherein the layer for encoding the surface points of interest Aᵢ comprises an intermediate sub-layer for encoding surface points of interest Aᵢ in a matrix representative of the geometry.

8. The neural network according to claim 7, wherein the module for generation of the intermediate vector representative of the geometry comprises a compression sub-module of the matrix representative of the geometry in order to obtain the intermediate vector representative of the geometry.

9. The neural network according to claim 8, wherein the compression sub-module is of a type from among “Max Pooling”, “Average Pooling” or “Sum Pooling”.

10. The neural network according to claim 8, wherein the compression sub-module corresponds to a decreasing cascade of sub-layers of the neural network.

11. The neural network according to claim 7, wherein the intermediate sub-layer for encoding the surface points of interest Aᵢ corresponds to an increasing cascade of sub-layers of the neural network.

12. The neural network according to claim 1, wherein the layer for generating a simulation result comprises a decreasing cascade of sub-layers of the neural network configured to generate at least one simulation value.

13. The neural network according to claim 1, characterized in that it is of the “Multi-Layer Perceptron” (MLP) or “Convolutional Neural Network” (CNN) type.

14. A method, implemented by computer, for numerical simulation of a physical phenomenon, such as flow of a fluid, heat transfer or a mechanical structure calculation, in a space including a plurality of surface points of interest Aᵢ linked to a geometry included in space, characterized in that the numerical simulation method comprises a step for prediction of a simulation result by the intermediary of a neural network according to claim 1, the simulation result including simulation values according to at least two different types, correlated with each other.

15. The method of numerical simulation according to claim 14, also comprising a learning phase during which parameters configuring each layer of the neural network are generated by learning from a plurality of numerical training simulations.

16. A computer program product, stored in a computer memory, comprising instructions configuring a computer processor for implementation of a numerical simulation method according to claim 14.

17. A method for configuration of a computer processor to simulate a physical phenomenon in a space, according to the implementation of a simulation method conforming to claim 15, comprising steps for:
receiving instructions for the simulation method, stored in a computer memory;
obtaining a result of simulation of the physical phenomenon from the processing of said instructions, the result of the simulation comprising simulation values of at least two different types, correlated with each other.
